(19) United States
(12) Patent Application Publication
(10) Pub. No.: US 2015/0287709 A1
(43) Pub. Date: Oct. 8, 2015

(54) DOUBLE PATTERNED STACKING TECHNIQUE

(71) Applicant: QUALCOMM Incorporated, San Diego, CA (US)

(72) Inventors: HariKrishna CHINTARLAPALLI REDDY, Bangalore (IN); Son LE, San Diego, CA (US); Ohsang KWON, San Diego, CA (US); Vijayalakshmi RANGANNA, Bangalore (IN)

(73) Assignee: QUALCOMM Incorporated, San Diego, CA (US)

(21) Appl. No.: 14/247,214

(22) Filed: Apr. 7, 2014

(51) Int. Cl. H01L 27/02; H01L 27/092

(52) U.S. Cl. CPC H01L 27/0207; H01L 27/0922

(57) ABSTRACT

A double patterned CMOS device includes a first set of stacked transistors, a second set of stacked transistors, and a set of transistors. The first set of stacked transistors includes first and second transistors. The first transistor has a first transistor active region and the second transistor has a second transistor active region. The second set of stacked transistors is adjacent the first set of stacked transistors. The second set of stacked transistors includes third and fourth transistors. The third transistor has a third transistor active region and the fourth transistor has a fourth transistor active region. The set of transistors is adjacent the first set of stacked transistors. The set of transistors includes a fifth transistor. The fifth transistor has a fifth transistor active region. The first, second, third, and fourth transistor active regions satisfy certain distance relationships from each other.

### BACKGROUND

1. Field

The present disclosure relates generally to a layout construction, and more particularly, to a double patterned stacking technique.

2. Background

A standard cell is an integrated circuit that may be implemented with digital logic. An application-specific integrated circuit (ASIC), such as a system-on-a-chip (SoC) device, may contain thousands to millions of standard cells. Reducing a size/area footprint of ASICs is beneficial. Accordingly, there is a need for reducing the size/area footprint of individual standard cells.

### SUMMARY

In an aspect of the disclosure, a complementary metal oxide semiconductor (CMOS) device includes a first set of stacked transistors including a first transistor and a second transistor. The first transistor has a first transistor active region and the second transistor has a second transistor active region. The CMOS device further includes a second set of stacked transistors adjacent the first set of stacked transistors. The second set of stacked transistors includes a third transistor and a fourth transistor. The third transistor has a third transistor active region and the fourth transistor has a fourth transistor active region. The CMOS device further includes a set of transistors adjacent the first set of stacked transistors. The set of transistors includes a fifth transistor. The fifth transistor has a fifth transistor active region. The first transistor active region is greater than or equal to a distance d from the second transistor active region. The third transistor active region is greater than or equal to the distance d from the fourth transistor active region. The distance d is a minimum distance based on a patterning process for the device. The first transistor active region is approximately greater than a distance 0.5d from the third transistor active region. The second transistor active region is approximately greater than the distance 0.5d from the fourth transistor active region. The fifth transistor active region is approximately greater than the distance 0.5d from the first transistor active region and the second transistor active region.

### BRIEF DESCRIPTION OF THE DRAWINGS

FIG. 1 is circuit diagram showing a plurality of sets of stacked transistors.

FIG. 2 is a diagram illustrating an exemplary layout of a CMOS device.

FIG. 3A and FIG. 3B are diagrams for further illustrating the exemplary layout of the CMOS device.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts. Apparatuses and methods will be described in the following detailed description and may be illustrated in the accompanying drawings by various blocks, modules, components, circuits, steps, processes, algorithms, elements, etc.

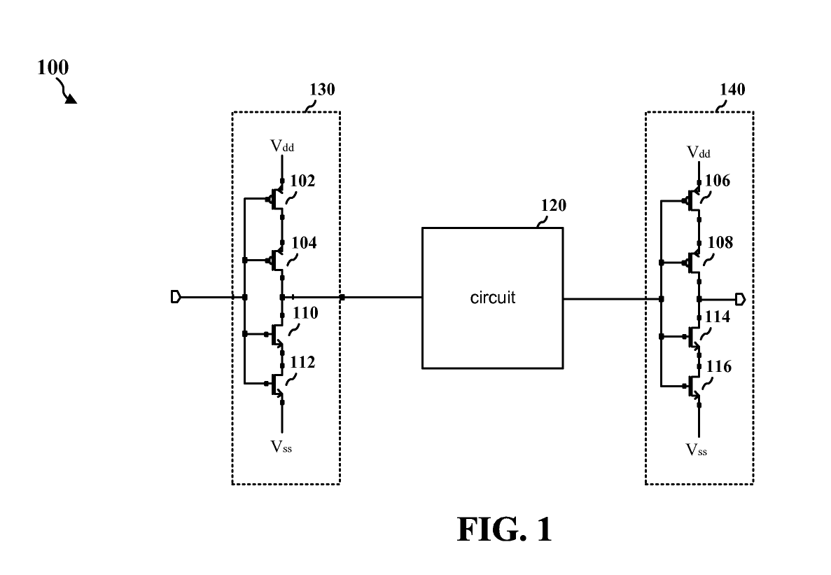

FIG. 1 is circuit diagram 100 showing a plurality of sets of stacked transistors. As shown in FIG. 1, the circuit 100 includes a first set of stacked transistors 130 coupled in series with a circuit 120 and a second set of stacked transistors 140. The first set of stacked transistors operates as an inverter and includes a p-type metal oxide semiconductor (pMOS) transistor 102, a pMOS transistor 104, an n-type metal oxide semiconductor (nMOS) transistor 110, and an nMOS transistor 112 coupled in series. The second set of stacked transistors operates as an inverter and includes a pMOS transistor 106, a pMOS transistor 108, an nMOS transistor 114, and an nMOS transistor 116 coupled in series.

In the schematic of the circuit 100, the first set of stacked transistors 130 and the second set of stacked transistors 140 are isolated from each other. However, in a layout of the circuit 100, the first set of stacked transistors 130 and the second set of stacked transistors 140 may be placed next to each other to satisfy a design rule check (DRC). A DRC may require that when a source/drain contact interconnect has a particular width (e.g., 26 nm) and a length less than a particular length (e.g., 150 nm), at least N (e.g., 5) source/drain interconnects be aligned to overlap by a particular percentage (e.g., 80%). The transistors 102-116 in the first and second sets of stacked transistors 130, 140 may be part of a scan chain and have smaller widths for a better scan hold margin. With the smaller widths, sets of the transistors 102-116 may be stacked within a height limited standard cell. For example, the first set of stacked transistors 130 may be stacked in a first stack and the second set of stacked transistors 140 may be stacked in a second stack within a standard cell.

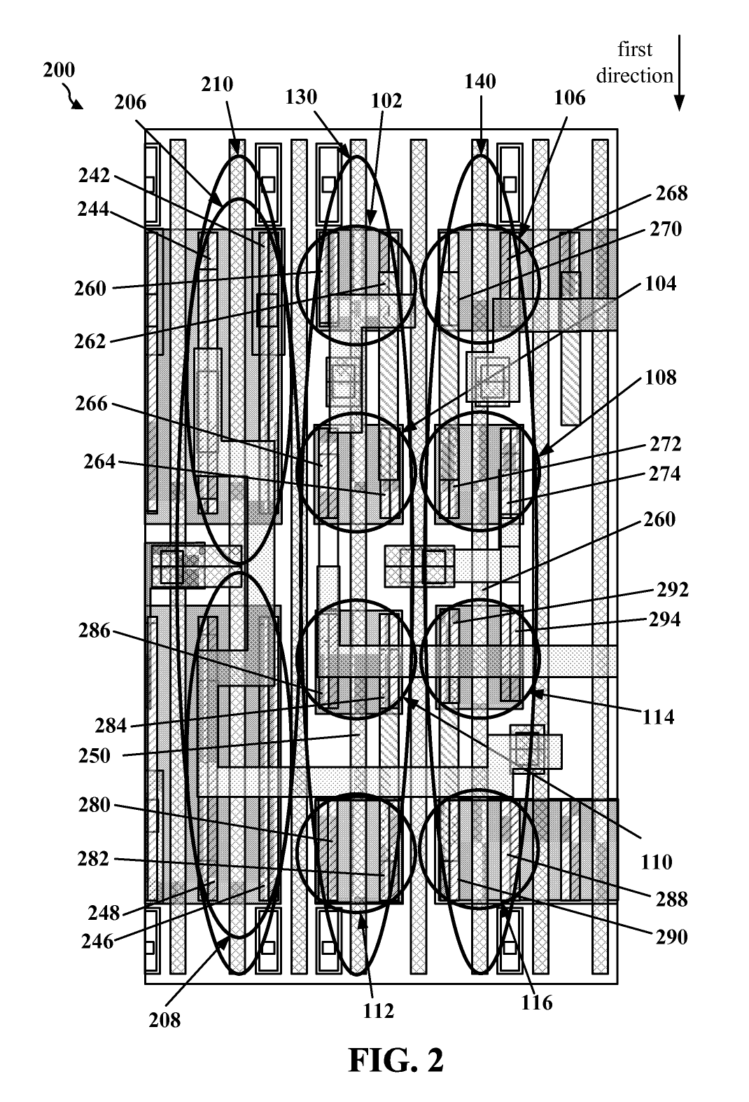

FIG. 2 is a diagram 200 illustrating an exemplary layout of a CMOS device. The diagram 200 illustrates a portion of a standard cell that includes the first set of stacked transistors 130, the second set of stacked transistors 140, and a set of transistors 210. The set of transistors 210 is within the circuit 120 of FIG. 1. The first set of stacked transistors 130 is stacked such that the pMOS transistor 102, the pMOS transistor 104, the nMOS transistor 110, and the nMOS transistor 112 share the same gate interconnect 250, which forms the gates of the each of the transistors 102, 104, 110, 112. The second set of stacked transistors 140 is stacked such that the pMOS transistor 106, the pMOS transistor 108, the nMOS transistor 114, and the nMOS transistor 116 share the same gate interconnect 260, which forms the gates of the each of the transistors 106, 108, 114, 116. The set of transistors 210 includes a transistor 206 and a transistor 208. The transistors 206 and 208 have a greater width than the transistors 102-116. The transistors 102-116, 206, and 208 are double patterned. In one configuration, the transistors 206, 208, 106, 108, 114, and 116 are patterned in one patterning process, and the transistors 102, 104, 110, and 112 are patterned in another patterning process.

Within the transistor 102, a source interconnect 260 contacts a source of the transistor 102 and a drain interconnect 262 contacts a drain of the transistor 102. Within the transistor 104, a source interconnect 264 contacts a source of the transistor 104 and a drain interconnect 266 contacts a drain of the transistor 104. Within the transistor 106, a source interconnect 268 contacts a source of the transistor 106 and a drain interconnect 270 contacts a drain of the transistor 106. Within the transistor 108, a source interconnect 272 contacts a source of the transistor 108 and a drain interconnect 274 contacts a drain of the transistor 108. Within the transistor 112, a source interconnect 280 contacts a source of the transistor 112 and a drain interconnect 282 contacts a drain of the transistor 112. Within the transistor 110, a source interconnect 284 contacts a source of the transistor 110 and a drain interconnect 286 contacts a drain of the transistor 110. Within the transistor 116, a source interconnect 288 contacts a source of the transistor 116 and a drain interconnect 290 contacts a drain of the transistor 116. Within the transistor 114, a source interconnect 292 contacts a source of the transistor 114 and a drain interconnect 294 contacts a drain of the transistor 114. Within the transistor 206, which may be a pMOS transistor, a source interconnect 242 contacts a source of the transistor 206 and a drain interconnect 244 contacts a drain of the transistor 206. Within the transistor 208, which may be an nMOS transistor, a source interconnect 246 contacts a source of the transistor 208 and a drain interconnect 248 contacts a drain of the transistor 208.

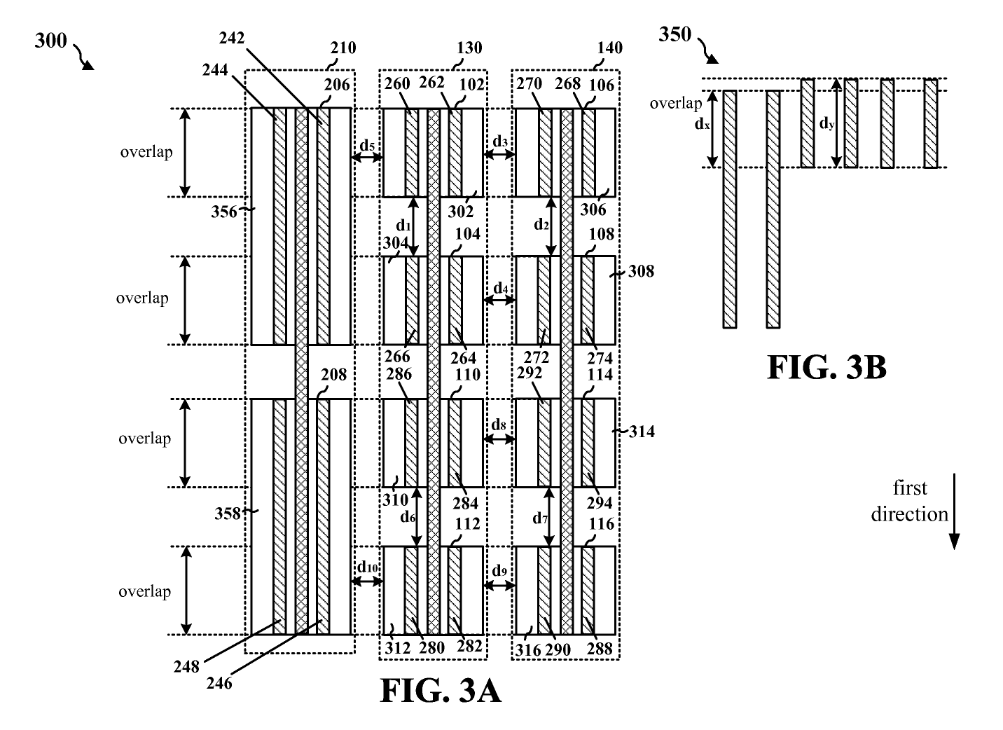

In one configuration, the source interconnect 260, the drain interconnect 262, the source interconnect 268, the drain interconnect 270, the source interconnect 242, and the drain interconnect 244 are aligned to overlap in a first direction. In one configuration, the source interconnect 264, the drain interconnect 266, the source interconnect 272, the drain interconnect 274, the source interconnect 242, and the drain interconnect 244 are aligned to overlap in the first direction. In one configuration, the source interconnect 280, the drain interconnect 282, the source interconnect 288, the drain interconnect 290, the source interconnect 246, and the drain interconnect 248 are aligned to overlap in the first direction (shown in FIG. 3A). In one configuration, the source interconnect 284, the drain interconnect 286, the source interconnect 292, the drain interconnect 294, the source interconnect 246, and the drain interconnect 248 are aligned to overlap in the first direction. As shown in FIG. 2, in the first direction, the overlap may be referred to as a vertical overlap. However, if the layout is rotated by 90°, the overlap may be referred to as a horizontal overlap. In one configuration, the overlaps may be at least 80% to satisfy the aforementioned DRC. As shown in FIG. 2, the overlaps are 100%.

FIG. 3A and FIG. 3B are diagrams 300 and 350, respectively, for further illustrating the exemplary layout of the CMOS device. The exemplary layout may apply to a particular manufacturing process (e.g., a 20 nm manufacturing process). Referring to FIG. 3A, a double patterned CMOS device includes a first set of stacked transistors 130 including a first transistor 102 and a second transistor 104. The first transistor 102 has a first transistor active region 302 and the second transistor 104 has a second transistor active region 304. A second set of stacked transistors 140 is adjacent the first set of stacked transistors 130. The second set of stacked transistors 140 includes a third transistor 106 and a fourth transistor 108. The third transistor 106 has a third transistor active region 306 and the fourth transistor 108 has a fourth transistor active region 308. A set of transistors 210 is adjacent the first set of stacked transistors 130. The set of transistors 210 includes a fifth transistor 206. The fifth transistor 206 has a fifth transistor active region 356. The first transistor active region 302 is a distance d₁ from the second transistor active region 304. The distance d₁ is greater than or equal to a distance d. The third transistor active region 306 is a distance d₂ from the fourth transistor active region 308. The distance d₂ is greater than or equal to the distance d. The first transistor active region 302 is a distance d₃ from the third transistor active region 306. The distance d₃ is greater than or approximately greater than a distance 0.5d. The second transistor active region 304 is a distance d₄ from the fourth transistor active region 308. The distance d₄ is greater than or approximately greater than the distance 0.5d. The fifth transistor active region 356 is a distance d₅ from the first transistor active region 302 and the second transistor active region 304. The distance d₅ is greater than or approximately greater than the distance 0.5d. The distance d is a minimum distance based on a patterning process for the device. Specifically, the distance d may be a minimum distance between active regions when the active regions are patterned at the same time with the same mask in the same patterning process. In one configuration, as shown in FIG. 3A, the distances d₁ and d₂ are equal, and the distances d₃ and d₄ are equal. In a subconfiguration, the distance d₅ may be equal to the distances d₃ and d₄.

In one configuration, the distances d₃, d₄, and d₅ are approximately less than the distance 0.6d. Accordingly, the distances d₃, d₄, and d₅ may be greater than the distance 0.5d and less than the distance 0.6d. For example, if the distance d=94 nm, then the distances d₃, d₄, and d₅ may be greater than 47 nm and less than 56.4 nm. In one configuration, the distances d₃, d₄, and d₅ are greater than or equal to 50 nm. In one example, the d₃, d₄, and d₅ are approximately equal to 50 nm. In one configuration, the distances d₁ and d₂ are less than or equal to the distance 1.2d. Accordingly, the distances d₁ and d₂ may be greater than or equal to the distance d and less than or equal to the distance 1.2d. In one configuration, the distances d₁ and d₂ are equal to the distance d. For example, if the distance d=94 nm, then the distances d₁ and d₂ are greater than or equal to 94 nm and less than or equal to 112.8 nm. In one example, the distances d₁ and d₂ are approximately equal to 94 nm.

As discussed supra, the fifth transistor active region 356, the third transistor active region 306, and the fourth transistor active region 308 are patterned together in one patterning process, and the first transistor active region 302 and the second transistor active region 304 are patterned together in another patterning process. The active regions 356, 306, 308 may be patterned before or after the active regions 302, 304.

The first transistor active region 302 includes a first transistor source and a first transistor drain. A first transistor source interconnect 260 contacts the first transistor source and a first transistor drain interconnect 262 contacts the first transistor drain. The third transistor active region 306 includes a third transistor source and a third transistor drain. A third transistor source interconnect 268 contacts the third transistor source and a third transistor drain interconnect 270 contacts the third transistor drain. The fifth transistor active region 356 includes a fifth transistor source and a fifth transistor drain. A fifth transistor source interconnect 242 contacts the fifth transistor source and a fifth transistor drain interconnect 244 contacts the fifth transistor drain. The first transistor source interconnect 260, the first transistor drain interconnect 262, the third transistor source interconnect 268, the third transistor drain interconnect 270, and at least one of the fifth transistor source interconnect 242 or the fifth transistor drain interconnect 244 (e.g., both the fifth transistor source interconnect 242 and the fifth transistor drain interconnect 244) are aligned to overlap in a first direction. In one configuration, the first transistor source interconnect 260, the first transistor drain interconnect 262, the third transistor source interconnect 268, the third transistor drain interconnect 270, and the at least one of the fifth transistor source interconnect 242 or the fifth transistor drain interconnect 244 (e.g., both the fifth transistor source interconnect 242 and the fifth transistor drain interconnect 244) are aligned to overlap in the first direction by at least 80% to satisfy the aforementioned DRC. Referring to FIG. 3B, the interconnect overlap is dₓ of a maximum possible overlap of d_{y}. In one configuration, dₓ/d_{y} is greater than or equal to 0.8. In one example, the interconnects 260, 262, 268, and 270 have a length of 100 nm (corresponding to a width of 100 nm for the transistors 102 and 106) and the overlap is greater than or equal to 80 nm.

The second transistor active region 304 includes a second transistor source and a second transistor drain. A second transistor source interconnect 264 contacts the second transistor source and a second transistor drain interconnect 266 contacts the second transistor drain. The fourth transistor active region 308 includes a fourth transistor source and a fourth transistor drain. A fourth transistor source interconnect 272 contacts the fourth transistor source and a fourth transistor drain interconnect 274 contacts the fourth transistor drain. In one configuration, the second transistor source interconnect 264, the second transistor drain interconnect 266, the fourth transistor source interconnect 272, the fourth transistor drain interconnect 274, and the at least one of the fifth transistor source interconnect 242 or the fifth transistor drain interconnect 244 (e.g., both the fifth transistor source interconnect 242 and the fifth transistor drain interconnect 244) are aligned to overlap in the first direction. In one configuration, the second transistor source interconnect 264, the second transistor drain interconnect 266, the fourth transistor source interconnect 272, the fourth transistor drain interconnect 274, and the at least one of the fifth transistor source interconnect 242 or the fifth transistor drain interconnect 244 (e.g., both the fifth transistor source interconnect 242 and the fifth transistor drain interconnect 244) are aligned to overlap in the first direction by at least 80% to satisfy the aforementioned DRC. Referring to FIG. 3B, the interconnect overlap is dₓ of a maximum possible overlap of d_{y}. In one configuration, dₓ/d_{y} is greater than or equal to 0.8. In one example, the interconnects 264, 266, 272, and 274 have a length of 100 nm (corresponding to a width of 100 nm for the transistors 104 and 108) and the overlap is greater than or equal to 80 nm.

The first set of stacked transistors 130 may further include a sixth transistor 110 and a seventh transistor 112. The sixth transistor 110 has a sixth transistor active region 310 and the seventh transistor 112 has a seventh transistor active region 312. The second set of stacked transistors 140 may further include an eighth transistor 114 and a ninth transistor 116. The eighth transistor 114 has an eighth transistor active region 314 and the ninth transistor 116 has a ninth transistor active region 316. The set of transistors 210 may further include a tenth transistor 208. The tenth transistor has a tenth transistor active region 358. The sixth transistor active region 310 is a distance d₆ from the seventh transistor active region 312. The distance d₆ may be greater than or equal to the distance d. The eighth transistor active region 314 is a distance d₇ from the ninth transistor active region 316. The distance d₇ may be greater than or equal to the distance d. The sixth transistor active region 310 is a distance d₈ from the eighth transistor active region 314. The distance d₈ may be approximately greater than the distance 0.5d. The seventh transistor active region 312 is a distance d₉ from the ninth transistor active region 316. The distance d₉ may be approximately greater than the distance 0.5d. The tenth transistor active region 358 is a distance d₁₀ from the sixth transistor active region 310 and the seventh transistor active region 312. The distance d₁₀ may be approximately greater than the distance 0.5d.

The distances d₆ and d₇ may be less than the distance 1.2d. Accordingly, the distances d₆ and d₇ may be greater than the distance d and less than the distance 1.2d. The distances d₈, d₉, and d₁₀ may be less than 0.6d. Accordingly, the distances d₈, d₉, and d₁₀ may be greater than the distance 0.5d and less than the distance 0.6d. In one configuration, as shown in FIG. 3A, the distances d₆ and d₇ are equal, and the distances d₈ and d₉ are equal. In another configuration, the distance d₁₀ may be equal to the distances d₈ and d₉. In one configuration, the distances d₁, d₂, d₆, and d₇ are approximately equal; the distances d₃, d₄, d₈, and d₉ are approximately equal; and the distances d₅ and d₁₀ are approximately equal. In another configuration, the distances d₁, d₂, d₆, and d₇ are approximately equal and the distances d₃, d₄, d₅, d₈, d₉, and d₁₀ are approximately equal.

The tenth transistor active region 358, the eighth transistor active region 314, and the ninth transistor active region 316 may be patterned together in one patterning process, and the sixth transistor active region 310 and the seventh transistor active region 312 may be patterned together in another patterning process. The tenth transistor active region 358, the eighth transistor active region 314, and the ninth transistor active region 316 may be patterned together along with the fifth transistor active region 356, the third transistor active region 306, and the fourth transistor active region 308 in one patterning process. The sixth transistor active region 310 and the seventh transistor active region 312 may be patterned together along with the first transistor active region 302 and the second transistor active region 304 in another patterning process. The active regions 356, 358, 306, 308, 314, and 316 may be patterned before or after the active regions 302, 304, 310, and 312.

The sixth transistor active region 310 includes a sixth transistor source and a sixth transistor drain. A sixth transistor source interconnect 384 contacts the sixth transistor source and a sixth transistor drain interconnect 388 contacts the sixth transistor drain. The eighth transistor active region 314 includes an eighth transistor source and an eighth transistor drain. An eighth transistor source interconnect 292 contacts the eighth transistor source and an eighth transistor drain interconnect 294 contacts the eighth transistor drain. The tenth transistor active region 358 includes a tenth transistor source and a tenth transistor drain. A tenth transistor source interconnect 246 contacts the tenth transistor source and a tenth transistor drain interconnect 248 contacts the tenth transistor drain. The sixth transistor source interconnect 284, the sixth transistor drain interconnect 286, the eighth transistor source interconnect 292, the eighth transistor drain interconnect 294, and at least one of the tenth transistor source interconnect 246 or the tenth transistor drain interconnect 248 (e.g., both the tenth transistor source interconnect 246 and the tenth transistor drain interconnect 248) are aligned to overlap in the first direction. In one configuration, the sixth transistor source interconnect 284, the sixth transistor drain interconnect 286, the eighth transistor source interconnect 292, the eighth transistor drain interconnect 294, and the at least one of the tenth transistor source interconnect 246 or the tenth transistor drain interconnect 248 (e.g., both the tenth transistor source interconnect 246 and the tenth transistor drain interconnect 248) are aligned to overlap in the first direction by at least 80% to satisfy the aforementioned DRC. Referring to FIG. 3B, the interconnect overlap is dₓ of a maximum possible overlap of d_{y}. In one configuration, dₓ/d_{y} is greater than or equal to 0.8. In one example, the interconnects 284, 286, 292, and 294 have a length of 100 nm (corresponding to a width of 100 nm for the transistors 110 and 114) and the overlap is greater than or equal to 80 nm.

The seventh transistor active region 312 includes a seventh transistor source and a seventh transistor drain. A seventh transistor source interconnect 280 contacts the seventh transistor source and a seventh transistor drain interconnect 282 contacts the seventh transistor drain. The ninth transistor active region 316 includes a ninth transistor source and a ninth transistor drain. A ninth transistor source interconnect 288 contacts the ninth transistor source and a ninth transistor drain interconnect 290 contacts the ninth transistor drain. The seventh transistor source interconnect 280, the seventh transistor drain interconnect 282, the ninth transistor source interconnect 288, the ninth transistor drain interconnect 290, and the at least one of the tenth transistor source interconnect 246 or the tenth transistor drain interconnect 248 (e.g., both the tenth transistor source interconnect 246 and the tenth transistor drain interconnect 248) are aligned to overlap in the first direction. In one configuration, the seventh transistor source interconnect 280, the seventh transistor drain interconnect 282, the ninth transistor source interconnect 288, the ninth transistor drain interconnect 290, and the at least one of the tenth transistor source interconnect 246 or the tenth transistor drain interconnect 248 (e.g., both the tenth transistor source interconnect 246 and the tenth transistor drain interconnect 248) are aligned to overlap in the first direction by at least 80% to satisfy the aforementioned DRC. Referring to FIG. 3B, the interconnect overlap is dₓ of a maximum possible overlap of d_{y}. In one configuration, dₓ/d_{y} is greater than or equal to 0.8. In one example, the interconnects 280, 282, 288, and 290 have a length of 100 nm (corresponding to a width of 100 nm for the transistors 112 and 116) and the overlap is greater than or equal to 80 nm.

The first set of stacked transistors 130 operate as an inverter. The first transistor 102 and the second transistor 104 are pMOS transistors, and the sixth transistor 110 and the seventh transistor 112 are nMOS transistors. The second set of stacked transistors 140 operate as an inverter. The third transistor 106 and the fourth transistor 108 are pMOS transistors, and the eighth transistor 114 and the ninth transistor 116 are nMOS transistors.

Referring to the distances d₁ through d₁₀, the distances d₃, d₄, d₅, d₈, d₉, and d₁₀ may be greater than or equal to the distance 0.5d and less than or equal to the distance 0.6d, where d is the minimum distance based on a patterning process for the device (discussed supra). In one configuration, d=94 nm and the distances d₃, d₄, d₅, d₈, d₉, and d₁₀ are greater than or equal to 47 nm and less than or equal to 56.4 nm. In one configuration, the distances d₃, d₄, d₅, d₈, d₉, and d₁₀ are greater than or equal to 50 nm and less than or equal to 56.4 nm. In another configuration, the distances d₃, d₄, d₅, d₈, d₉, and d₁₀ are equal to 50 nm. The distances d₁, d₂, d₆, and d₇ may be greater than or equal to the distance d and less than or equal to the distance 1.2d. In one configuration, d=94 nm and the distances d₁, d₂, d₆, and d₇ are greater than or equal to 94 nm and less than or equal to 112.8 nm. In another configuration, the distances d₁, d₂, d₆, and d₇ are equal to the distance d. If d=94 nm, then the distances d₁, d₂, d₆, and d₇ are equal to 94 nm.

As discussed supra, a DRC may require that when interconnects have a particular width (e.g., 26 nm) and a length less than a particular length (e.g., 150 nm), at least N (e.g., 5) of the interconnects be aligned to overlap by a particular percentage (e.g., 80%). The configurations as provided supra may satisfy the DRC. The interconnects 260, 262, 268, 270, 242, and 244 may be a first group of interconnects; the interconnects 264, 266, 272, 274, 242, and 244 may be a second group of interconnects; the interconnects 284, 286, 292, 294, 246, and 248 may be a third group of interconnects; and the interconnects 280, 282, 288, 290, 246, and 248 may be a fourth group of interconnects. Each of the first, second, third, and fourth groups of interconnects may overlap by 80%. As shown in FIG. 3A, each of the groups overlap by 100%. Further, the interconnects within the first, second, third, and fourth groups of interconnects may satisfy the aforementioned distances between the interconnects as provided supra.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.” Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A double patterned complementary metal oxide semiconductor (CMOS) device comprising:
a first set of stacked transistors comprising a first transistor and a second transistor, the first transistor having a first transistor active region and the second transistor having a second transistor active region;
a second set of stacked transistors adjacent the first set of stacked transistors, the second set of stacked transistors comprising a third transistor and a fourth transistor, the third transistor having a third transistor active region and the fourth transistor having a fourth transistor active region; and
a set of transistors adjacent the first set of stacked transistors, the set of transistors comprising a fifth transistor, the fifth transistor having a fifth transistor active region,
wherein the first transistor active region is greater than or equal to a distance d from the second transistor active region, the third transistor active region is greater than or equal to the distance d from the fourth transistor active region, the distance d is a minimum distance based on a patterning process for the device, the first transistor active region is approximately greater than a distance 0.5d from the third transistor active region, the second transistor active region is approximately greater than the distance 0.5d from the fourth transistor active region, and the fifth transistor active region is approximately greater than the distance 0.5d from the first transistor active region and the second transistor active region.

2. The device of claim 1, wherein the first transistor active region is approximately less than the distance 0.6d from the third transistor active region, the second transistor active region is approximately less than the distance 0.6d from the fourth transistor active region, and the fifth transistor active region is approximately less than the distance 0.6d from the first transistor active region and the second transistor active region.

3. The device of claim 1, wherein the first transistor active region is less than or equal to the distance 1.2d from the second transistor active region, and the third transistor active region is less than or equal to the distance 1.2d from the fourth transistor active region.

4. The device of claim 1, wherein the fifth transistor active region, the third transistor active region, and the fourth transistor active region are patterned together in one patterning process, and the first transistor active region and the second transistor active region are patterned together in another patterning process.

5. The device of claim 1, wherein the first transistor active region comprises a first transistor source and a first transistor drain, a first transistor source interconnect contacts the first transistor source and a first transistor drain interconnect contacts the first transistor drain, the third transistor active region comprises a third transistor source and a third transistor drain, a third transistor source interconnect contacts the third transistor source and a third transistor drain interconnect contacts the third transistor drain, the fifth transistor active region comprises a fifth transistor source and a fifth transistor drain, and a fifth transistor source interconnect contacts the fifth transistor source and a fifth transistor drain interconnect contacts the fifth transistor drain; wherein the first transistor source interconnect, the first transistor drain interconnect, the third transistor source interconnect, the third transistor drain interconnect, and at least one of the fifth transistor source interconnect or the fifth transistor drain interconnect are aligned to overlap in a first direction.

6. The device of claim 5, wherein the first transistor source interconnect, the first transistor drain interconnect, the third transistor source interconnect, the third transistor drain interconnect, and the at least one of the fifth transistor source interconnect or the fifth transistor drain interconnect are aligned to overlap in the first direction by at least 80%.

7. The device of claim 5, wherein the second transistor active region comprises a second transistor source and a second transistor drain, a second transistor source interconnect contacts the second transistor source and a second transistor drain interconnect contacts the second transistor drain, the fourth transistor active region comprises a fourth transistor source and a fourth transistor drain, a fourth transistor source interconnect contacts the fourth transistor source and a fourth transistor drain interconnect contacts the fourth transistor drain; wherein the second transistor source interconnect, the second transistor drain interconnect, the fourth transistor source interconnect, the fourth transistor drain interconnect, and the at least one of the fifth transistor source interconnect or the fifth transistor drain interconnect are aligned to overlap in the first direction.

8. The device of claim 7, wherein the second transistor source interconnect, the second transistor drain interconnect, the fourth transistor source interconnect, the fourth transistor drain interconnect, and the at least one of the fifth transistor source interconnect or the fifth transistor drain interconnect are aligned to overlap in the first direction by at least 80%.

9. The device of claim 1, wherein the first set of stacked transistors further comprises a sixth transistor and a seventh transistor, the sixth transistor has a sixth transistor active region and the seventh transistor has a seventh transistor active region, the second set of stacked transistors further comprises an eighth transistor and a ninth transistor, the eighth transistor has an eighth transistor active region and the ninth transistor has a ninth transistor active region, the set of transistors further comprises a tenth transistor, and the tenth transistor has a tenth transistor active region; wherein the sixth transistor active region is greater than or equal to the distance d from the seventh transistor active region, the eighth transistor active region is greater than or equal to the distance d from the ninth transistor active region, the sixth transistor active region is approximately greater than the distance 0.5d from the eighth transistor active region, the seventh transistor active region is approximately greater than the distance 0.5d from the ninth transistor active region, and the tenth transistor active region is approximately greater than the distance 0.5d from the sixth transistor active region and the seventh transistor active region.

10. The device of claim 9, wherein the tenth transistor active region, the eighth transistor active region, and the ninth transistor active region are patterned together in one patterning process, and the sixth transistor active region and the seventh transistor active region are patterned together in another patterning process.

11. The device of claim 9, wherein the sixth transistor active region comprises a sixth transistor source and a sixth transistor drain, a sixth transistor source interconnect contacts the sixth transistor source and a sixth transistor drain interconnect contacts the sixth transistor drain, the eighth transistor active region comprises an eighth transistor source and an eighth transistor drain, an eighth transistor source interconnect contacts the eighth transistor source and an eighth transistor drain interconnect contacts the eighth transistor drain, the tenth transistor active region comprises a tenth transistor source and a tenth transistor drain, and a tenth transistor source interconnect contacts the tenth transistor source and a tenth transistor drain interconnect contacts the tenth transistor drain; wherein the sixth transistor source interconnect, the sixth transistor drain interconnect, the eighth transistor source interconnect, the eighth transistor drain interconnect, and at least one of the tenth transistor source interconnect or the tenth transistor drain interconnect are aligned to overlap in a first direction.

12. The device of claim 11, wherein the sixth transistor source interconnect, the sixth transistor drain interconnect, the eighth transistor source interconnect, the eighth transistor drain interconnect, and the at least one of the tenth transistor source interconnect or the tenth transistor drain interconnect are aligned to overlap in the first direction by at least 80%.

13. The device of claim 11, wherein the seventh transistor active region comprises a seventh transistor source and a seventh transistor drain, a seventh transistor source interconnect contacts the seventh transistor source and a seventh transistor drain interconnect contacts the seventh transistor drain, the ninth transistor active region comprises a ninth transistor source and a ninth transistor drain, a ninth transistor source interconnect contacts the ninth transistor source and a ninth transistor drain interconnect contacts the ninth transistor drain; wherein the seventh transistor source interconnect, the seventh transistor drain interconnect, the ninth transistor source interconnect, the ninth transistor drain interconnect, and the at least one of the tenth transistor source interconnect or the tenth transistor drain interconnect are aligned to overlap in the first direction.

14. The device of claim 13, wherein the seventh transistor source interconnect, the seventh transistor drain interconnect, the ninth transistor source interconnect, the ninth transistor drain interconnect, and the at least one of the tenth transistor source interconnect or the tenth transistor drain interconnect are aligned to overlap in the first direction by at least 80%.

15. The device of claim 9, wherein the first set of stacked transistors operate as an inverter, the first transistor and the second transistor being p-type metal oxide semiconductor (pMOS) transistors, the sixth transistor and the seventh transistor being n-type metal oxide semiconductor (nMOS) transistors.

16. The device of claim 9, wherein the second set of stacked transistors operate as an inverter, the third transistor and the fourth transistor being p-type metal oxide semiconductor (pMOS) transistors, the eighth transistor and the ninth transistor being n-type metal oxide semiconductor (nMOS) transistors.

17. The device of claim 9, wherein d is approximately equal to 94 nm.

18. The device of claim 9, wherein the sixth transistor active region is greater than or equal to a distance 50 nm from the eighth transistor active region, the seventh transistor active region is greater than or equal to the distance 50 nm from the ninth transistor active region, and the tenth transistor active region is greater than or equal to the distance 50 nm from the sixth transistor active region and the seventh transistor active region.

19. The device of claim 9, where the sixth transistor active region is approximately less than the distance 0.6d from the eighth transistor active region, the seventh transistor active region is approximately less than the distance 0.6d from the ninth transistor active region, and the tenth transistor active region is approximately less than the distance 0.6d from the sixth transistor active region and the seventh transistor active region.

20. The device of claim 1, wherein the first transistor active region is greater than or equal to a distance 50 nm from the third transistor active region, the second transistor active region is greater than or equal to the distance 50 nm from the fourth transistor active region, and the fifth transistor active region is greater than or equal to the distance 50 nm from the first transistor active region and the second transistor active region.
